(19) United States
(12) Patent Application Publication
(10) Pub. No.: US 2008/0151466 A1
(43) Pub. Date: Jun. 26, 2008

(54) ELECTROSTATIC CHUCK AND METHOD OF FORMING

(75) Inventor: Matthew A. Simpson, Sudbury, MA (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: SAINT-GOBAIN CERAMICS & PLASTICS, INC., Worcester, MA (US)

(21) Appl. No.: 11/960,340

(22) Filed: Dec. 19, 2007

Related U.S. Application Data
(60) Provisional application No. 60/871,880, filed on Dec. 26, 2006.

(51) Int. Cl. H01L 21/683; H01R 43/00

(52) U.S. Cl. 361/234; 29/825

(57) ABSTRACT

An electrostatic chuck is disclosed which includes a substrate, a patterned conductive layer overlying the substrate, such that the patterned conductive layer is defining electrode pathways separated by gaps. The electrostatic chuck also includes a resistive layer overlying the patterned conductive layer and a low-k dielectric layer overlying the substrate and disposed in the gaps between the electrode pathways. The low-k dielectric layer includes a material having a different phase than the material of the substrate.

### CROSS-REFERENCE TO RELATED APPLICATION(S)

The present application claims priority from U.S. Provisional Patent Application No. 60/871,880, filed Dec. 26, 2006, entitled “ELECTROSTATIC CHUCK AND METHOD OF FORMING”, naming inventor Matthew A. Simpson, which application is incorporated by reference herein in its entirety.

### BACKGROUND

1. Field of the Disclosure

This disclosure is directed to an electrostatic chuck (ESC) and is particularly directed to an electrostatic chuck for holding electrically insulating workpieces.

2. Description of the Related Art

Chucks are used to support and hold wafers and substrates in place within high temperature and corrosive processing chambers such as those used for chemical vapor deposition, physical vapor deposition, or etching. Several main types of chucks have been developed. Mechanical chucks stabilize wafers on a supporting surface by using mechanical holders. Mechanical chucks have a disadvantage in that they often cause distortion of workpieces due to non-uniform forces being applied to the wafers. Thus, wafers are often chipped or otherwise damaged, resulting in a lower yield. Vacuum chucks operate by lowering the pressure between the wafer and the chuck below that of the chamber, thereby holding the wafer. Although the force applied by vacuum chucks is more uniform than that applied by mechanical chucks, improved performance is desired. In this respect, pressures in the chamber during semiconductor manufacturing processes tend to be quite low, and sufficient force cannot always be applied.

Recently, electrostatic chucks (ESCs) have been used to hold workpieces in a processing chamber. Electrostatic chucks work by utilizing a voltage difference between the workpiece and electrodes which can be embedded in the body of the electrostatic chuck, and may apply a more uniform force than mechanical chucks or vacuum chucks.

Broadly, there exist two types of ESCs: a unipolar type and a bipolar type. The unipolar, or parallel plate ESC includes a single electrode and relies upon plasma used within the processing chamber to form the second “electrode” and provide the necessary attractive forces to hold the substrate in place on the chucking surface. The bipolar, or integrated electrode ESC, includes two electrodes of opposite polarity within the chuck body and relies upon the electric field generated between the two electrodes to hold the workpiece in place.

Additionally, in an ESC, the chucking of a wafer can be achieved using a Coulombic force or Johnsen-Rahbek (JR) effect. Chucks using a JR effect achieve efficient chucking performance through the flow of charges through a dielectric layer. ESCs utilizing a Coulombic force are advantageous when using a plasma which provides the necessary second electrode to create a capacitive chucking force on the workpiece.

Despite improvements in ESCs, various industries continue to demand improved performance, for example, those industries processing larger, more massive substrates and workpieces. Notably, the glass industry and particularly the display industry are moving rapidly to produce displays of larger size. This shift to processing of larger workpieces, generally within high temperature and corrosive processing environments, places further demands on ESCs used during processing.

### SUMMARY

According to one aspect, an electrostatic chuck is disclosed which includes a substrate and a patterned conductive layer overlying the substrate. The patterned conductive layer defines electrode pathways that are separated by gaps. The electrostatic chuck further includes a resistive layer overlying the patterned conductive layer, and a low-k dielectric layer overlying the substrate and disposed in the gaps between the electrode pathways. The low-k dielectric layer includes a material having a different phase than the material of the substrate.

According to another aspect, a method of forming an electrostatic chuck is disclosed which includes providing a substrate and forming a conductive layer made of a conductive material overlying the substrate. The method further includes forming a resistive layer made of a resistive material overlying the conductive layer, and forming a patterned conductive layer and resistive layer having electrode pathways made of the conductive material, wherein the electrode pathways are separated by gaps and the resistive layer overlies the electrode pathways. The method further includes forming a low-k dielectric layer within the gaps.

According to another aspect a method of forming an electronic device is provided which includes providing an electrostatic chuck having (i) a substrate, and (ii) a patterned conductive layer overlying the substrate, such that the patterned conductive layer defining electrode pathways separated by gaps. The electrostatic chuck also includes (iii) a resistive layer overlying the patterned conductive layer defining a work surface, and (iv) a low-k dielectric layer overlying the substrate and disposed in the gaps between the electrode pathways, wherein the low-k dielectric layer comprises a material having a different phase than the material of the substrate. The method further includes providing a workpiece overlying the work surface, providing a voltage across the electrostatic chuck to maintain the workpiece in proximity to the work surface, and processing the workpiece to form an electronic device.

### BRIEF DESCRIPTION OF THE DRAWINGS

The present disclosure may be better understood, and its numerous features and advantages made apparent to those skilled in the art by referencing the accompanying drawings.

FIG. 1A is a flow chart illustrating a method of forming an electrostatic chuck according to an embodiment.

FIG. 1B is a cross-sectional illustration of layers formed during the formation of an electrostatic chuck according to an embodiment.

FIG. 1C is a cross-sectional illustration of layers formed during the formation of an electrostatic chuck according to an embodiment.

FIG. 1D is a cross-sectional illustration of layers formed during the formation of an electrostatic chuck according to an embodiment.

FIG. 1E is a cross-sectional illustration of layers formed during the formation of an electrostatic chuck according to an embodiment.

FIG. 2 is a cross-sectional illustration of a portion of an electrostatic chuck according to an embodiment.

FIG. 3 is a cross-sectional illustration of a portion of an electrostatic chuck according to an embodiment.

FIG. 4 is a cross sectional view of a portion of an electrostatic chuck according to an embodiment.

FIG. 5 is a top view of an interdigitated electrode pattern according to an embodiment.

FIG. 6 is a top view of an interdigitated electrode pattern according to an embodiment.

The use of the same reference symbols in different drawings indicates similar or identical items.

### DESCRIPTION OF THE EMBODIMENT(S)

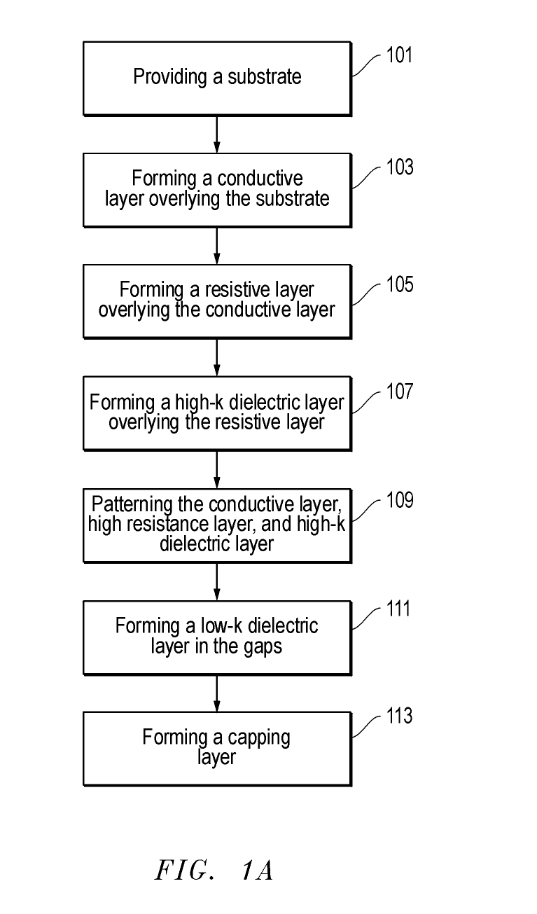

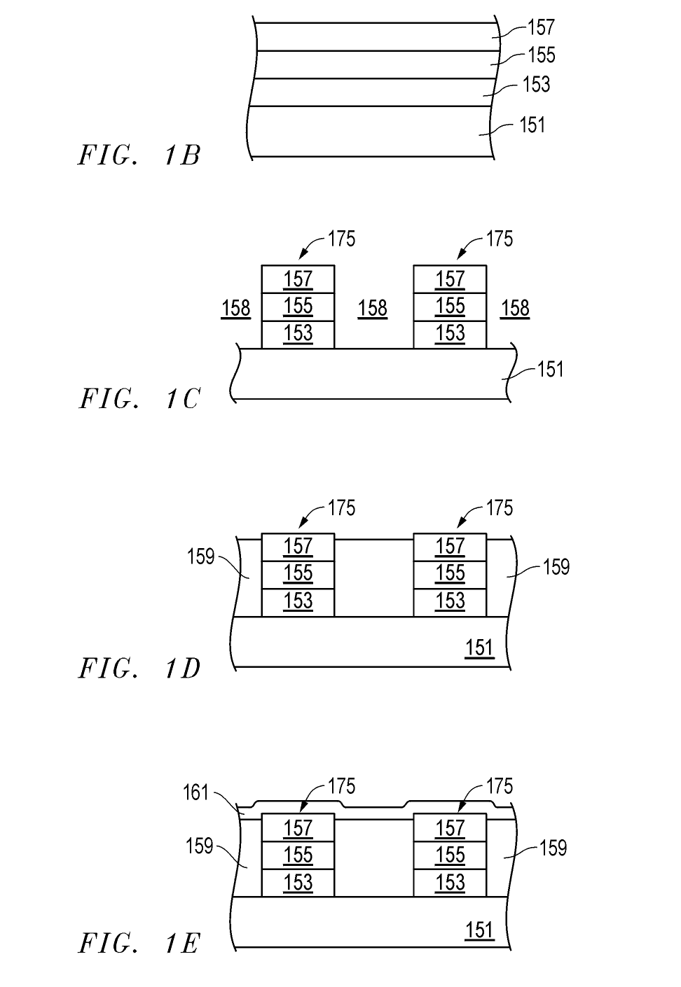

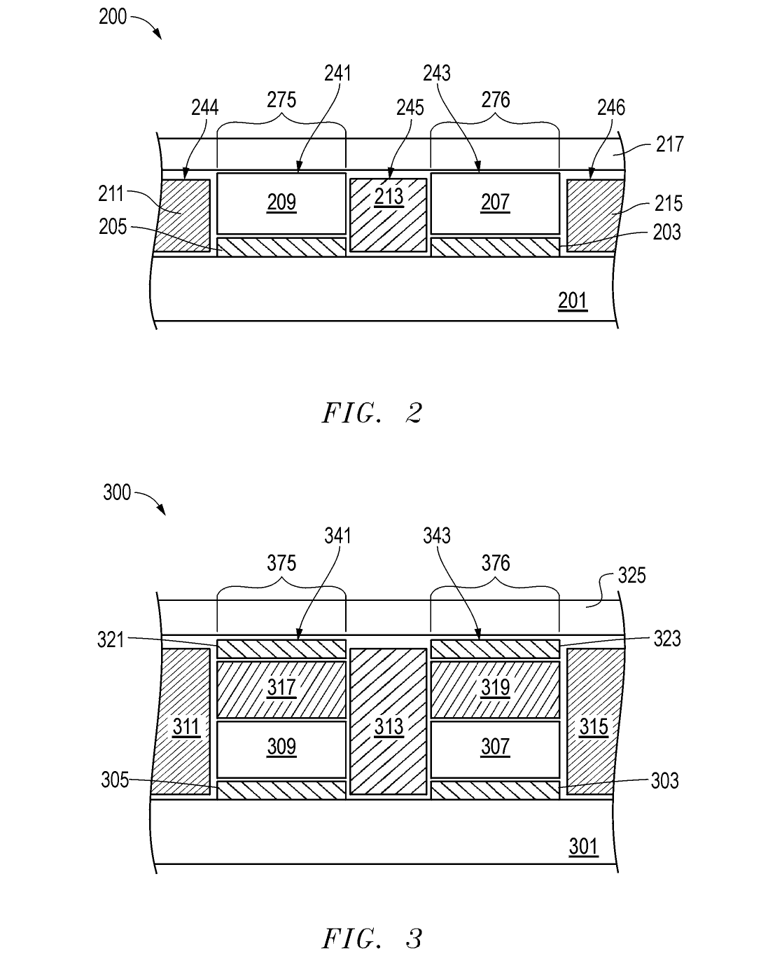

Referring to FIGS. 1A through 1E, a method according to an embodiment is initiated at step 101 by providing a substrate 151 suitable for forming overlying layers thereon. Suitable materials for the substrate 151 generally include inorganic materials. According to one particular embodiment, inorganic materials can include insulating materials, such as single crystalline, polycrystalline, or amorphous inorganic materials including ceramics, glass-ceramics, and glasses. Suitable compositions are oftentimes oxide based, such as aluminum oxide or silicon oxide-based, formed from a composition containing a majority of aluminum oxide or silicon oxide, and may be in the form of a complex oxide or multiphase material.

Other suitable inorganic materials for the substrate 151 can include conductors such as metals and metal alloys. Suitable metals generally include aluminum, ferrous metals, or combinations thereof. In applications where a high stiffness-to-weight is needed, the use of a silicon carbide substrate may be advantageous. In embodiments utilizing a conductive substrate 151, the conductor forms a base of the substrate, and a coating can be applied to a surface of the base. Generally the overlying layer, noted above, is in contact with the coating. Such a coating can also be an inorganic composition, generally being single crystal, polycrystalline, or amorphous. Suitable coating materials generally include insulating materials, such as a ceramic, glass-ceramic, or glass material. As such, suitable insulating materials can be oxide-based materials, such as yttrium oxide, aluminum oxide, zirconium oxide, or silicon oxide. Such oxides can be compound oxides or multiphase oxides.

Generally, the substrate 151 is a robust component having a thickness of greater than about 2 mm, such as greater than about 10 mm, and in some cases greater than 25 mm. Moreover, the substrate is generally a dense material suitable for forming layers thereon. Accordingly, the porosity of the substrate is generally less than about 10 vol %, such as less than about 5.0 vol %, and in some instances, less than about 1.0 vol %.

In reference to those embodiments utilizing a substrate having a coating, generally the coating is a dense structure. As such, the porosity of the coating is generally not greater than about 20 vol %, such as not greater than about 10 vol %, and even, not greater than about 5.0 vol %.

Referring again to FIGS. 1A through 1E, the method according to the illustrated embodiment further provides a step 103 of forming a conductive layer 153 overlying the substrate 151. The formation of the conductive layer 153 is generally carried out by a deposition process, including, for example a thick film deposition process such as printing, or spraying (e.g., thermal spraying), or a thin film deposition process such as chemical vapor deposition or physical vapor deposition. In the context of a thermal spraying process, plasma spraying may be utilized.

The conductive layer 153 is generally formed of an inorganic material, generally an electrically conductive material, such as a conductive metal, or metal alloy. Suitable metals can include high temperature metals such as titanium, molybdenum, nickel, copper, tungsten, iron, silicon, aluminum, and combinations or alloys thereof. In one particular embodiment, the conductive layer 153 includes molybdenum. Generally, the conductive layer 153 includes not less than about 50 wt % metal species, such as not less than about 80 wt % metal species, or even not less than about 95 wt % metal species. According to one particular embodiment, the conductive layer 153 is made entirely of a metal species, which may be in the form of a metal alloy.

The conductive layer 153 can be a composite material, and as such, in addition to the conductive material, the conductive layer 153 can contain adhesion promoters. Such adhesion promoters can be inorganic materials, such as conductive, semiconductive or even insulating materials. Suitable materials can be single crystal, polycrystalline, or amorphous, such as for example, ceramics, glass-ceramics, or glasses. Particularly suitable adhesion promoters can include oxide-based materials, such as yttrium oxide, aluminum oxide, zirconium oxide, hafnium oxide, titanium oxide, chromium oxide, iron oxide, silicon oxide, barium titanate, tantalum oxide, barium oxide, or compound oxides thereof. According to one particular embodiment, a suitable adhesion promoter is the same material of the underlying layer and/or overlying layer.

Adhesion promoters are generally present within the conductive layer 153 in an amount of less than about 75 vol %, such as less than about 50 vol %, and even less than about 25 vol %. Accordingly, the amount of adhesion promoter can be less, such that the conductive layer 153 contains not greater than about 10 vol %.

In reference to the electrical characteristics of the conductive layer 153, generally the resistivity of the conductive layer 153 at room temperature is not greater than about 10³ Ohm-cm, such as not greater than about 10¹ Ohm-cm. Still, in other embodiments, the resistivity of the conductive layer is not greater than about 10⁻¹ Ohm-cm. The sheet resistance of the conductive layer 153 is generally less than 10⁷ Ohms, such as less than about 10⁶ Ohms, or not less than 10⁶ Ohms.

Accordingly, in one embodiment the conductive layer 153 is formed via a thermal spraying process during which the adhesion promoter material is provided simultaneously with the conductor material (e.g., a metal). In one particular embodiment, the conductive layer 153 is formed via a spraying process that utilizes a composite powder composition, which includes the conductor material and the adhesion promoter. The composite powder composition, comprises not less than about 25 vol % conductor material, such as not less than about 35 vol % conductor material, and in particular instances, not less than about 50 vol % conductor. The composite powder composition typically includes not greater than about 75 vol % adhesion promoter, such as not greater than about 50 vol % adhesion promoter, and even not greater than about 25 vol % adhesion promoter.

The conductive layer 153 is generally a thinner layer in comparison to the substrate 151, and generally has a thickness of not greater than about 200 microns. According to one embodiment, the conductive layer 153 has an average thickness of not greater than about 100 microns, and in some instances not greater than about 50 microns.

In further reference to FIGS. 1A through 1E, after forming the conductive layer 153, a resistive layer 155 is formed according to step 105, to overlie the conductive layer 153. Formation of the resistive layer 155 can be carried out by a deposition process, including, for example a thick film deposition process such as printing or spraying (e.g., thermal spraying) or a thin film deposition process such as chemical vapor deposition or physical vapor deposition. In the context of a thermal spraying process, plasma spraying may be utilized. Noteworthy, thermal spraying may produce a lamellar grain structure or microstructure, which is advantageous for reducing high voltage breakdown. The lamellar microstructure generally results from the rapid solidification of small globules of the material thermally sprayed at high velocities, which flatten from striking the comparatively cold surface of the layer on which it is being deposited.

The resistive layer 155 is generally a robust layer and can have average thicknesses of greater than about 100 microns, such as greater than about 200 microns, and in some cases greater than about 300 microns. Still, the resistive layer 155 is generally not greater than about 600 microns, and according to one embodiment, the average thickness of the resistive layer 155 is within a range of between about 200 microns to about 500 microns. The resistive layer 155 can be a dense layer having minimized porosity, which is generally closed porosity. The average porosity of the resistive layer 155 can be not greater than about 10 vol %, such as not greater than about 5.0 vol %. According to one particular embodiment, the resistive layer has a porosity of not greater than about 1.0 vol %.

The resistive layer 155 is described herein as such due to its particular electrical properties relative to the underlying conductive layer 153. More particularly, the resistive layer 155 can have a resistivity that is at least an order of magnitude more resistive than the underlying conductive layer 153. Its resistance may be greater than about 10⁴ Ohm/cm², such as greater than about 10⁵ Ohm/cm², as measured between the top and the bottom faces of the layer. The resistance however, may be limited, for example to less than about 10¹⁰ Ohm/cm². According to another embodiment, the resistive layer 155 has a resistance of less than about 10⁹ Ohm/cm², such as less than about 10⁸ Ohm/cm², such as within a range of between about 10⁴ Ohm/cm² and about 10⁸ Ohm/cm². The foregoing resistance values are normalized to the surface area of a contact. In particular, the resistance is measured with upper and lower contacts, each having a surface area, and as such the resistance is normalized for the total surface area of the contacts.

The resistive layer 155 generally includes an inorganic material, and particularly semiconductive materials, which can include a single crystal, polycrystalline, or amorphous material. Suitable semiconductive materials can include ceramics, glass-ceramics, or glasses. According to one embodiment, the resistive layer 155 can include an oxide-based material. Suitable oxide-based materials can include for example, aluminum oxide, silicon oxide, zirconium oxide, haffiium oxide, titanium oxide, chromium oxide, yttrium oxide, iron oxide, barium oxide, haffiium oxide, manganese oxide, cobalt oxide, nickel oxide, copper oxide, zinc oxide, niobium oxide, tin oxide, cadmium oxide, gallium oxide, and tantalum oxide. Certain oxide-based species are particularly adapted to be combined with modifiers. For example, aluminum oxide and/or zirconium oxide alone may be combined with other materials, such as for example titanium oxide, to decrease the resistivity.

Additionally, the resistive layer 155 may include other inorganic materials, such as an ionic conductor. Suitable ionic conductors generally include materials having a glass-ceramic or glass phase, such as solid electrolyte materials. According to one embodiment, suitable ionic conductors can include oxide-based materials, such as silicates. Particularly suitable silicate materials include doped silicate materials. Doped silicate materials can be doped with ions, such as cations, and particularly monovalent cations, such as Li. Other ionic conductors can include fluorine-based materials, particularly fluorine-based materials having a glass phase. Suitable fluorine-based materials can include fluorine compositions having transition metals, for example, lanthanum fluoride. As such, the fluorine-based materials can be doped with a cation, particularly a divalent cation, such as Ca.

After forming the resistive layer 155, formation of a high-k dielectric layer 157 overlying the conductive layer 153 and resistive layer 155 can be completed at step 107. Formation of the high-k dielectric layer 157 can be carried out by a deposition process, including, for example a thick film deposition process such as printing or spraying (e.g., thermal spraying) or a thin film deposition process such as chemical vapor deposition or physical vapor deposition. In the context of a thermal spraying process, plasma spraying may be utilized. The high-k dielectric layer 157 may advantageously have a lamellar microstructure, which may be produced by the thermal spray process and which may be effective to increase the dielectric strength of the resistive layer. Description of lamellar structures is provided above in connection with the resisvtive layer.

The high-k dielectric layer 157 can contain an inorganic or organic material, or a combination of both. According to one embodiment, the high-k dielectric layer 157 includes inorganic materials such as ceramics, glass-ceramics, or glasses. Such materials generally include oxide-based materials, such as, aluminum oxide, titanium oxide, chromium oxide, yttrium oxide, iron oxide, barium oxide, haffiium oxide, zirconium oxide, barium titanate, tantalum oxide, lead magnesium niobate, sodium-bismuth titanates, lithium tantalate and combinations and compound oxides thereof. According to a particular embodiment, the high-k dielectric includes at least one of, titanium oxide, chromium oxide, barium titanate, haffiium oxide, or zirconium oxide, or a combination or compound oxide thereof. Certain oxide-based species are particularly adapted to be combined with modifiers. For example, aluminum oxide and yttrium oxide alone may be combined with other materials to increase the dielectric constant of the high-k dielectric layer. Species such as iron oxide may be combined with other materials, typically oxide-based materials, to form a combination or compound oxide material having an increased resistivity.

As provided above, the high-k dielectric layer 157 can include an organic material. The organic material can include polymers, and may particularly include non-ionic polymers, and/or non-polar polymers. Generally suitable polymers can include polyolefins, such as polyethylene, polypropylene, and polybutene. Additionally, polymers such as polyimides and polyamides can be used. Other suitable polymer compositions can include, polyesters, polyethers, acrylates, and silicones, such as dialkylpolysiloxane and fluorosilicates. Such organic compounds facilitate reduced porosity and typically do not comprise greater than about 50 wt % of the high-k dielectric layer 157. Other embodiments utilize smaller amounts, such that the high-k dielectric layer 157 includes less than about 25 wt %, such as less than about 10 wt %, or even less than about 5.0 wt % of an organic compound.

Generally, the high-k dielectric layer 157 has a dielectric constant of not less than about 10. According to one embodiment, the high-k dielectric layer 157 has a dielectric constant of not less than about 15, such as not less than about 20, and in particular instances not less than about 25.

Generally, the high-k dielectric layer 157 is a robust layer having an average thickness of not less than about 100 microns. According to one embodiment, the high-k dielectric layer 157 has an average thickness of not less than about 200 microns, such as not less than about 300 microns. Still, the high-k dielectric layer 157 has an average thickness generally not greater than about 600 microns. In one embodiment, the high-k dielectric layer 157 has an average thickness within a range of between about 200 microns to about 500 microns.

After forming a high-k dielectric layer 157, patterning at step 109 may be carried out to pattern the conductive layer 153, resistive layer 155, and high-k dielectric layer 157. Patterning is generally carried out to form electrical pathways, depicted in the cross-sectional illustration of FIG. 1C as electrode stacks 175, that can form alternating electrodes (anodes and cathodes) according to one embodiment. In one particular embodiment, patterning of the conductive layer 153, resistive layer 155, and high-k dielectric layer 157 includes removing a portion of the respective layers to form gaps 158, such that the electrode pathways are separated by the gaps 158 as shown in FIG. 1C. Patterning may be carried out by a lithographic technique, including chemical and mechanical removal approaches. Mechanical etching can include physical removal of portions of the layers using, for example, laser ablation, cutting, abrasion, and/or erosion techniques. A chemical etching process can include a wet etch process or a dry etch process. In one particular embodiment, the chemical etching process may utilize a mask. For example, etching can include a photolithographic process which can include application of a photoresist, a masking step, a light exposure step, and then an etching step after removing portions of the mask utilizing a chemical species effective to dissolve or react with the constituent layer undergoing selective removal.

Referring again to FIGS. 1A through 1E, after patterning the conductive layer 153, resistive layer 155, and high-k dielectric layer 157, a low-k dielectric layer 159 may be formed within the gaps 158 according to step 111. Formation of the low-k dielectric layer 159 in the gaps 158 can be completed by a deposition process. Selective deposition can be carried out by pouring low-k dielectric material or a precursor thereof in liquid form, into the gaps, followed by solidification. In the case of an organic low-k dielectric material, solidification can be carried out by evaporation of solvent and/or crosslinking by exposure to actinic radiation or thermal energy. Non-selective deposition processes generally coat the entire patterned structure, generally requiring material removal post-deposition to expose the electrode stacks 175, thereby selectively leaving behind low-k material between the electrode stacks 175. Such deposition processes can include, for example, a thick film deposition process such as printing or spraying (e.g., thermal spraying) or a thin film deposition process such as chemical vapor deposition or physical vapor deposition. In the context of a thermal spraying process, plasma spraying may be utilized.

The process of forming the low-k dielectric layer 159, particularly in the context of a non-selective deposition, can further include a selective removal process in which a portion of the low-k dielectric layer 159 is removed to expose the top surface of the electrode stacks 175. Such a selective removal process can include a mechanical or chemical process. According to one embodiment, a mechanical process can include a selective grinding or polishing step, such as one utilizing an abrasive having a particular hardness. The selective removal process can also include a chemical process, which may be used alone or in conjunction with a mechanical process, such as a chemical mechanical polishing process (CMP). Such a chemical process can include a selective etching process in which an etchant, such as an acid, is used to remove portions of the low-k dielectric layer 159.

Generally the low-k dielectric layer 159 has a dielectric constant not greater than about 10. According to one embodiment, the low-k dielectric layer 159 has a dielectric constant of not greater than about 8.0, such as not greater than about 5.0, not greater than about 3.0, or even not greater than about 2.0. In a particular embodiment, the dielectric constant of the low-k dielectric layer 159 is within a range of between about 2.0 and about 8.0.

Further, the low-k dielectric layer 159 is resistive. For example, the low-k dielectric layer may have a resistivity of not less than about 10⁸ Ohm-cm, such as not less than about 10⁹ Ohm-cm, or not greater than 10¹¹ Ohm-cm. According to another embodiment, the resistivity of the low-k dielectric layer 159 is not less than about 10¹² Ohm-cm, such as not less than about 10¹³ Ohm-cm, or not less than about 10¹⁴ Ohm-cm. In one embodiment, the resistivity of the low-k dielectric layer 159 is within a range of between about 10⁹ Ohm-cm and about 10¹⁴ Ohm-cm. According to a particular embodiment, the low-k dielectric layer 159 has a resistivity that is at least 10 times greater than the resistivity of the resistive layer 155. In another embodiment, the resistivity of the low-k dielectric layer 159 is not less than about 100 times greater, or even, not less than about 1000 times greater than the resistivity of the resistive layer 155.

In further reference to the materials of the low-k dielectric layer, notably, the low-k dielectric layer 159 includes a material having a different phase than the material of the substrate, for example a different crystalline phase, often a different composition. Generally, the low-k dielectric layer 159 includes an inorganic material, such as a polycrystalline or amorphous material. Particularly suitable materials can include ceramic, glass-ceramic, or glass materials, such as for example, fluorine-based materials or oxide-based materials. Suitable oxide-based materials can include, for example silicon oxide or aluminum oxide. Such oxide-based materials can include compound oxides or multiphase materials. Additionally, the low-k dielectric layer 159 can incorporate an organic material. The organic material can include polymers, which may include non-ionic polymers, and/or non-polar polymers. Generally, suitable polymers can include polyolefins, such as polyethylene, polypropylene, and polybutene. Additionally, polymers such as polyimides and polyamides can be used. Other suitable polymer compositions can include, polyesters, polyethers, acrylates, and silicones, such as dialkylpolysiloxane and fluorosilicates.

According to one embodiment, the low-k dielectric layer utilizes both inorganic and organic components. Generally, the organic material is used as an additive or filler material for additional stabilization of the inorganic component. Accordingly, the concentration of such additives within the low-k dielectric layer is less than about 50 wt %, such as less than about 25 wt %, and in even less than about 10 wt %.

The low-k dielectric layer 159 typically has a thickness on the order of the total thickness of the electrode stacks 175. The low-k dielectric layer 159 generally has an average thickness of greater than about 100 microns, such as greater than about 300 microns. According to one embodiment, the low-k dielectric layer has an average thickness of less than about 600 microns, such as less than about 400 microns. Further, the low-k dielectric layer 159, the layer is generally dense. The low-k dielectric layer generally has a porosity of not greater than about 10 vol %, wherein such porosity is generally closed porosity. In another embodiment, the low-k dielectric layer has a porosity of not greater than about 5.0 vol %, such as not greater than about 2.0 vol %.

Generally, the low-k dielectric layer 159 has a thickness less than the total thickness of the electrode stacks 175, such that there is a step distance from the top surface of the electrode stacks 175 down to the top surface of the low-k dielectric layer. According to one embodiment, the average step distance is not less than about 5.0 microns, such as not less than about 10 microns, and even, at not less than about 20 microns.

According to a particular feature of an embodiment, the low-k and high-k dielectric layers have a particular dielectric constant ratio. Dielectric constant ratio is defined herein as the ratio between the dielectric constant of the low-k dielectric layer 159 and the dielectric constant of the high-k dielectric layer 157. In one embodiment, the dielectric ratio is not less than about 1.0:1.5, such as not less than 1.0:2.0. In another embodiment, the dielectric ratio is not less than about 1.0:2.5, or not less than about 1.0:3.0, or even not less than 1.0:4.0.

Referring to FIGS. 1A through 1E, after forming the low-k dielectric layer 159, a capping layer 161 can be formed at step 113. According to one embodiment, the capping layer 161 is conformal, formed such that it overlies the entirety of the ESC structure including the substrate 151, the electrode stacks 175 and the low-k dielectric layer 159.

In reference to the materials comprising the capping layer 161, the capping layer generally includes an inorganic material, such as a polycrystalline or amorphous material, which may include a ceramic, glass-ceramic, or glass material. Particularly suitable materials can include oxide-based materials, such as aluminum oxide and yttrium oxide, or combinations thereof. Such materials can be compound oxides or multiphase oxides. In reference to such oxide materials, generally the capping layer 161 comprises a high purity content of those oxides to reduce potential contamination to the workpieces. The capping layer 161 generally includes not less than about 75 wt % oxide-based material.

Generally the capping layer 161 is a thin layer in comparison to the dielectric layers. As such, the capping layer 161 generally has an average thickness of not greater than about 100 microns, such as not greater than about 75 microns, and in some instances not greater than about 50 microns. According to one particular embodiment, the capping layer 161 has an average thickness within a range of between about 10 microns and about 50 microns. According to various embodiments, the capping layer 161 has an average thickness limited by the thickness of the high-k dielectric layer 157, such that the average thickness of the capping layer is not greater than about 60% of the average thickness of the high-k dielectric layer 157. According to other embodiments, the average thickness of the capping layer 161 is not greater than about 50%, not greater than about 45%, or not greater than about 40% of the average thickness of the high-k dielectric layer 157. The thickness of the capping layer 161 may be further limited by average electrode spacing, discussed in more detail below.

Referring to FIG. 2, a cross-sectional view of a portion of the layers comprising an electrostatic chuck 200 is illustrated according to one particular embodiment. As illustrated, the chuck 200 includes a substrate 201, electrode portions 205 and 203, and resistive layer portions 209 and 207 overlying electrodes portions 205 and 203 respectively. The electrode portions 205 and 203 and the resistive layer portions 209 and 207 form the electrode stacks 275 and 276. The electrostatic chuck 200 further illustrates low-k dielectric portions 211, 213, and 215 between resistive layer portions 209 and 207. Overlying all such layers is a workpiece 217.

In particular reference to the electrode portions 205 and 203, as described previously, adjacent electrodes within the electrostatic chuck have opposite polarities such that a cathode is adjacent two anodes and vice versa. Accordingly, electrode portion 205 can be an anode and electrode portion 203 can be a cathode, or alternatively, electrode portion 205 can be a cathode and electrode portion 203 can be an anode.

As illustrated in this embodiment, the top surfaces of the resistive layer portions 209 and 207 protrude from surrounding layers and form the receiving surfaces 241 and 243 for receiving and holding the workpiece 217. Notably, the top surfaces 244, 245, and 246 (244-246) of the low-k dielectric portions 211, 213, and 215 are formed such that they are not co-planar with the receiving surfaces 241 and 243 and form a step as described above. Moreover, in another embodiment, the corners of the resistant layer portions 209 and 207 can be rounded, and particularly those corners at the receiving surfaces 241 and 243 can be rounded, to reduce the likelihood of arcing between electrode stacks 275 and 276. The radius of curvature of the rounded corners can be not less than about 1.0 micron, such as not less than about 5.0 microns, and even, not less than about 10 microns.

Referring to FIG. 3, a cross-sectional view of portions of layers within an electrostatic chuck 300 is illustrated according to an embodiment. Electrostatic chuck 300 includes a substrate 301, electrode portions 305 and 303 overlying the substrate, and resistive layer portions 309 and 307 overlying the electrode portions 305 and 303. The electrostatic chuck 300 further includes high-k dielectric layer portions 317 and 319 overlying resistive layer portions 309 and 307, and capping layer portions 321 and 323 overlying only the high-k dielectric layer portions 317 and 319. The above described portions form the electrode stacks 375 and 376.

The electrostatic chuck 300 further includes low-k dielectric portions 311, 313, and 315 overlying the substrate and disposed within gaps between the electrode stacks 375 and 376. The electrostatic chuck 300 further includes receiving surfaces 341 and 343, which protrude from the top surface for receiving a workpiece 325 which are defined by the top surfaces of the capping layer portions 321 and 323. Notably, while previous embodiments describe the capping layer as a conformal layer overlying the entire surface of the electrostatic chuck, FIG. 3 illustrates that in one embodiment, the capping layer is patterned and overlies only the electrode stacks 375 and 376. Such a structure may be accomplished by depositing the capping layer prior to patterning. Low-k dielectric portions 311, 313, and 315 are not coplanar with the top surfaces of capping layer portions 321 and 323, and as such do not provide a receiving surface for the workpiece 325. Alternatively, it will be appreciated that other embodiments can utilize a low-k dielectric layer which is coplanar with the receiving surface and defines the receiving surface.

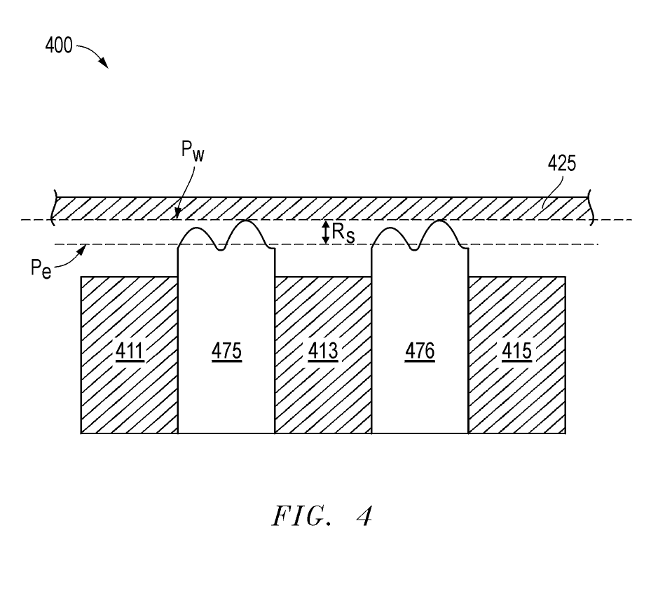

Referring to FIG. 4, a cross-sectional illustration of a portion of an electrostatic chuck 400 is illustrated. FIG. 4 illustrates electrode stacks 475 and 476, with low-k dielectric layer portions 411, 413, and 415 within the gaps between the electrode stacks 475 and 476. The top surfaces of the electrode stacks 475 and 476 provide the receiving surface upon which a workpiece 425 is held. According to embodiments provided herein, the electrode stacks 475 and 476 can include a combination of layers, and as such, the receiving surface is defined by the upper most layer within the electrode stacks 475 and 476. The upper most layer can include the resistive layer, the high-k dielectric layer, or the capping layer (including either conformal or selective capping layer structures), and accordingly the top surface of one of these respective layers forms the receiving surface. The receiving surface is generally a smooth surface have a surface roughness (Rₛ), which is defined herein as the distance between a plane (Pw) overlying and intersecting the highest peaks of the electrode stacks and a parallel plane (Pe) in which not less than 75% of the total surface area of the electrode stacks lie above for a 1.0 cm² area of the receiving surface. According to one embodiment, the receiving surface has surface roughness (Rₛ) of not greater than about 40 microns. Other embodiments utilize a smoother receiving surface, such that the receiving surface has a surface roughness of not greater than about 20 microns, or even, not greater than about 10 microns.

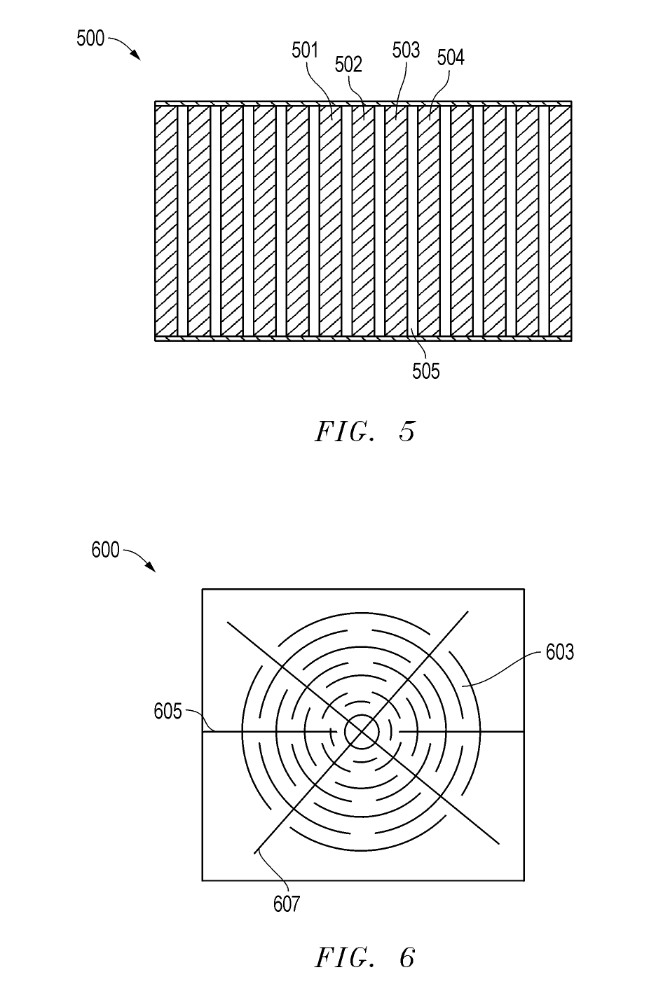

Referring to FIG. 5, a top view of an electrostatic chuck 500 is illustrated. Notably, FIG. 5 illustrates a patterned surface, notably an interdigitated pattern of electrode pathways including an alternating configuration of cathodes 501 and 503, and anodes 502 and 504 that are separated by gaps 505. According to a particular embodiment, the electrode pathways generally have an average width of not less than about 0.05 millimeters, such as not less than about 0.1 millimeters, and in some instances not less than about 1.0 millimeters. Still, the electrode pathways generally have an average width of not greater than about 5.0 millimeters, such as not greater than about 4.0 millimeters. In reference to the width of the gaps 505 between the electrode pathways, generally the average width of the gaps is not less than about 0.1 millimeters, such as not less than about 1.0 millimeter. The gaps 505 typically have an average width of not greater than about 5.0 millimeters, such as not greater than about 4.0 millimeters.

Generally, the width of the electrode pathways and the gaps have a relationship that can be expressed by a width ratio. As used herein, the width ratio is the width of the conductive pathways as compared to the width of the gaps. According to one embodiment, the width ratio is not less than about 0.05, such as not less than about 0.1, and in some instances not less than about 0.3. According to one particular embodiment, the width ratio is generally within a range of between 0.1 to about 0.9, such that the width ratio is generally not greater than about 1.0.

Moreover, the thickness of the capping layer may be limited by the average electrode spacing, or the width of the gaps. According to one embodiment, the average thickness of the capping layer is not greater than about 30% of the average width of the gaps. As such, the average thickness may be less by comparison, such that it is not greater than about 25%, or not greater than about 15%, or even not greater than about 10% of the average width of the gaps.

Referring to FIG. 6, another top view of an electrode pattern of an electrostatic chuck 600 is illustrated. The electrostatic chuck 600 illustrates an alternate pattern comprising electrode pathways 601 separated by gaps 603. As provided in other embodiments, the electrode pathways 601 include electrodes of different polarities. As such, in one embodiment, electrode 605 is an anode and electrode 607 is a cathode.

In reference to the dimensions of the entire electrostatic chuck, according to one particular embodiment, the electrostatic chuck has a rectangular contour. As such, in one embodiment the electrostatic chuck has an average length of not less than about 0.5 meters, such as not less than about 0.75 meters, or even, not less than about 1.0 meter. Accordingly, the electrostatic chuck has a comparable width, and typically has an average width of not less than about 0.5 meters, such as not less than about 0.75 meters, and in some instances not less than about 1.0 meter.

This disclosure also provides a method of forming an electronic device using an electrostatic chuck as described in embodiments herein. Once the electrostatic chuck is provided within the processing chamber a workpiece can be provided to the work surface of the electrostatic chuck. According to embodiments herein, the work surface of the electrostatic chucks generally includes a high-k dielectric layer or a capping layer. The workpiece can be provided in proximity to the work surface. The workpiece can generally include an inorganic material and particularly is formed principally of a glass phase, such as a silicon-oxide based component. According to one embodiment, the workpiece is a display panel, intended for final application as a display, or the like. Notably, such displays can include liquid crystal displays (LCDs), plasma displays, electroluminescent displays, displays utilizing thin-film-transistors (TFTs), and the like.

Generally, the workpieces can be large and in some cases, rectangular in shape, such that they have a length of not less than about 0.25 m, such as not less than about 0.5 m or even not less than about 1.0 m. Accordingly, the average width of such workpieces is generally not less than about 0.25 m, such as not less than about 0.5 m, and still, not less than about 1.0 m.

According to one embodiment, an electrostatic chuck and workpiece can be provided within a processing chamber for processing. Generally, processing of the workpiece can include chemical processing, such as a photolithography and chemical processing, and more particularly can include a masking, etching, or deposition process, or a combination of all such processes. In one embodiment, processing of the workpiece includes etching, such as a plasma etching process. According to another embodiment, processing of the workpiece includes a thin-film deposition process, such as one utilizing a vapor deposition process, such as chemical vapor deposition (CVD), and particularly a plasma assisted CVD process.

According to one embodiment, processing of the workpiece includes forming electronic devices on the workpiece, such as transistors, and more particularly, processing of the workpiece includes forming a series of transistors, or an array of transistors, such as a TFT. As such, the workpiece can undergo multiple masking, deposition and etching processes. Moreover, such a process can include deposition of metals, semiconductive materials, and insulating materials.

Generally, such processing is undertaken at reduced pressures, and according to one embodiment, processing of the workpiece is done at a pressure of not greater than about 0.5 atm, such as not greater than about 0.3 atm, or not greater than about 0.1 atm.

According to embodiments described above, an electrostatic chuck having a bipolar design incorporating an interdigitated electrode pattern in cooperation with multiple layers is provided. In particular, present embodiments describe a combination of features including, a bipolar and interdigitated electrode design, patterned layers having particular compositions, geometries, and electrical characteristics, as well as a particular architectural design. The combination of features disclosed in the embodiments herein provide electrostatic chucks particularly well-suited for performing effective chucking operations in corrosive environments. In the particular context of large substrates, the embodiments herein disclose electrostatic chucks capable of holding large insulating workpieces, particularly insulating workpieces that require the use of large electrical potentials, such as those in excess of 3 kV. As such, the electrostatic chucks provided herein are well-suited to effectively hold such workpieces, avoid catastrophic failure, and exhibit improved durability.

While the invention has been illustrated and described in the context of specific embodiments, it is not intended to be limited to the details shown, since various modifications and substitutions can be made without departing in any way from the scope of the present invention. For example, additional or equivalent substitutes can be provided and additional or equivalent production steps can be employed. As such, further modifications and equivalents of the invention herein disclosed may occur to persons skilled in the art using no more than routine experimentation, and all such modifications and equivalents are believed to be within the scope of the invention as defined by the following claims.

1. An electrostatic chuck comprising:
a substrate;
a patterned conductive layer overlying the substrate, the patterned conductive layer defining electrode pathways separated by gaps;
a resistive layer overlying the patterned conductive layer; and
a low-k dielectric layer overlying the substrate and disposed in the gaps between the electrode pathways, wherein the low-k dielectric layer comprises a material having a different phase than the material of the substrate.

2. (canceled)

3. The electrostatic chuck of claim 1, wherein the resistive layer comprises an oxide-based material.

4-10. (canceled)

11. The electrostatic chuck of claim 1, wherein the resistive layer has a resistance of less than about 10¹⁰ Ohm-cm².

12. The electrostatic chuck of claim 11, wherein the resistive layer has a resistance of greater than about 10⁴ Ohm/cm².

13. The electrostatic chuck of claim 1, wherein the low-k dielectric layer comprises a material having a dielectric constant of not greater than about 10.

14-15. (canceled)

16. The electrostatic chuck of claim 1, wherein the low-k dielectric layer comprises an oxide-based material.

17. (canceled)

18. The electrostatic chuck of claim 1, wherein the low-k dielectric layer comprises an organic material.

19. The electrostatic chuck of claim 18, wherein the organic material comprises a material selected from the group of materials consisting of polyimides, polyamides, polyolefins, silicones, acrylates, and polyesters.

20-23. (canceled)

24. The electrostatic chuck of claim 1, wherein the low-k dielectric layer has a resistivity of not less than about 10⁸ Ohm-cm.

25-26. (canceled)

27. The electrostatic chuck of claim 1, wherein the low-k dielectric layer has a resistivity of not less than about 10 times the resistivity of the resistive layer.

28. (canceled)

29. The electrostatic chuck of claim 1, wherein the gaps have an average width of not greater than about 5.0 mm.

30. (canceled)

31. The electrostatic chuck of claim 1, wherein the electrode pathways have an average width of not less than about 0.05 mm.

32-40. (canceled)

41. The electrostatic chuck of claim 1, wherein the electrostatic chuck has a patterned top surface.

42. The electrostatic chuck of claim 41, wherein the patterned top surface comprises protrusions of the electrode pathways above the low-k dielectric material within the gaps.

43. The electrostatic chuck of claim 42, wherein the protrusions of the electrode pathways define a receiving surface, the receiving surface having a surface roughness (Rₛ) of not greater than about 40 microns.

44-45. (canceled)

46. The electrostatic chuck of claim 1, wherein the patterned conductive layer comprises a width ratio between a width of the conductive pathways and a width of the gaps of not less than about 0.05.

47. (canceled)

48. The electrostatic chuck of claim 1, wherein a high-k dielectric layer overlies the resistive layer.

49-50. (canceled)

51. The electrostatic chuck of claim 48, wherein the dielectric ratio between the low-k dielectric material and the high-k dielectric material is not less than about b 1.0:1.5.

51-53. (canceled)

54. The electrostatic chuck of claim 48, wherein the high-k dielectric layer comprises an oxide-based material selected from the group of oxide materials consisting of aluminum oxide, titanium oxide, chromium oxide, yttrium oxide, iron oxide, barium oxide, hafnium oxide, zirconium oxide, barium titanium oxide, and tantalum oxide.

55. (canceled)

56. The electrostatic chuck of claim 48, wherein the high-k dielectric layer defines a receiving surface having a surface roughness (Rₛ) of not greater than about 40 microns.

57. The electrostatic chuck of claim 1, wherein a capping layer overlies the resistive layer and the low-k dielectric layer.

58-62. (canceled)

63. A method of forming an electrostatic chuck comprising:
providing a substrate;
forming a conductive layer comprising a conductive material overlying the substrate;
forming a resistive layer comprising a resistive material overlying the conductive layer;
patterning the conductive layer and the resistive layer to form electrode pathways, defined by electrode stacks including the conductive layer and the resistive layer, wherein the electrode stacks are separated by gaps; and
forming a low-k dielectric layer within the gaps.

64-74. (canceled)

75. The method of claim 63, wherein the low-k dielectric layer is formed so as to have a reduced thickness relative to the electrode stacks.

76. The method of claim 63, wherein the method further comprises forming a high-k dielectric layer overlying the resistive layer, and patterning is carried out after forming the high-k dielectric layer such that the high-k dielectric layer is part of the electrode stacks.

77. (canceled)

78. A method of forming an electronic device comprising:
providing an electrostatic chuck comprising (i) a substrate, (ii) a patterned conductive layer overlying the substrate, the patterned conductive layer defining electrode pathways separated by gaps, (iii) a resistive layer overlying the patterned conductive layer defining a work surface, and (iv) a low-k dielectric layer overlying the substrate and disposed in the gaps between the electrode pathways, wherein the low-k dielectric layer comprises a material having a different phase than the material of the substrate;
providing a workpiece overlying the work surface;
providing a voltage across the electrostatic chuck to maintain the workpiece in proximity to the work surface; and
processing the workpiece to form an electronic device.

79-87. (canceled)
